(19) United States
(12) Patent Application Publication
(10) Pub. No.: US 2015/0263034 A1
(43) Pub. Date: Sep. 17, 2015

(54) SEMICONDUCTOR MEMORY DEVICE AND MANUFACTURING METHOD OF THE SAME

(71) Applicant: Kabushiki Kaisha Toshiba, Minato-ku (JP)

(72) Inventors: Masaaki HIGUCHI, Yokkaichi (JP); Hirokazu ISHIGAKI, Yokkaichi (JP); Masao SHINGU, Yokkaichi (JP); Katsuyuki SEKINE, Yokkaichi (JP)

(73) Assignee: Kabushiki Kaisha Toshiba, Minato-ku (JP)

(21) Appl. No.: 14/482,579

(22) Filed: Sep. 10, 2014

(30) Foreign Application Priority Data
Mar. 17, 2014 (JP) 2014-053922

(51) Int. Cl. H01L 27/115; H01L 29/51; H01L 21/02; H01L 21/28

(52) U.S. Cl. CPC H01L 27/11582; H01L 21/28282; H01L 29/513; H01L 21/02164; H01L 21/0217

(57) ABSTRACT

According to one embodiment, a semiconductor memory device includes a stacked body having a plurality of electrode layers containing boron and silicon, and a plurality of insulating layers each provided between the electrode layers; a channel body penetrating through the stacked body; and a memory film provided between the channel body and each of the electrode layer. The memory film includes a tunnel film, a charge storage film, and a block film, provided in order from the channel body side. The block film includes a silicon nitride film, and a first silicon oxide film provided between the silicon nitride film and the electrode layer and being in contact with the electrode layer.

### CROSS-REFERENCE TO RELATED APPLICATION

This application is based upon and claims the benefit of priority from Japanese Patent Application No. 2014-053922, filed on Mar. 17, 2014; the entire contents of which are incorporated herein by reference.

### FIELD

Embodiments described herein relate generally to a semiconductor memory device and a manufacturing method of a semiconductor memory device.

### BACKGROUND

There has been proposed a memory device having a three-dimensional structure in which a memory hole is formed in a stacked body obtained by stacking, via an insulating layer, a plurality of electrode layers functioning as a control gate in a memory cell, and in which a silicon body serving as a channel has been provided on a side wall of the memory hole via a charge storage film. In addition, although a silicon layer containing an impurity has been proposed as the electrode layer in such three-dimensional memory device, high reliability is required for the electrode layer.

### BRIEF DESCRIPTION OF THE DRAWINGS

FIG. 1 is a schematic perspective view of a semiconductor memory device of an embodiment;

FIG. 2 is a schematic cross-sectional view of the semiconductor memory device of the embodiment;

FIGS. 3A and 3B are enlarged schematic cross-sectional views of the semiconductor memory device of the embodiment;

FIG. 4 to FIG. 9 are schematic cross-sectional views showing a method for manufacturing the semiconductor memory device of the embodiment; and

FIG. 10 is a schematic perspective view of a semiconductor memory device of an embodiment.

### DETAILED DESCRIPTION

According to one embodiment, a semiconductor memory device includes a stacked body having a plurality of electrode layers containing boron and silicon, and a plurality of insulating layers each provided between the electrode layers; a channel body penetrating through the stacked body and extending in a stacking direction of the stacked body; and a memory film provided between the channel body and each of the electrode layer. The memory film includes a tunnel film, a charge storage film, and a block film, provided in order from the channel body side. The block film includes a silicon nitride film, and a first silicon oxide film provided between the silicon nitride film and the electrode layer and being in contact with the electrode layer.

An embodiment will now be described with reference to drawings. The same components are marked with the same numerals in each drawing.

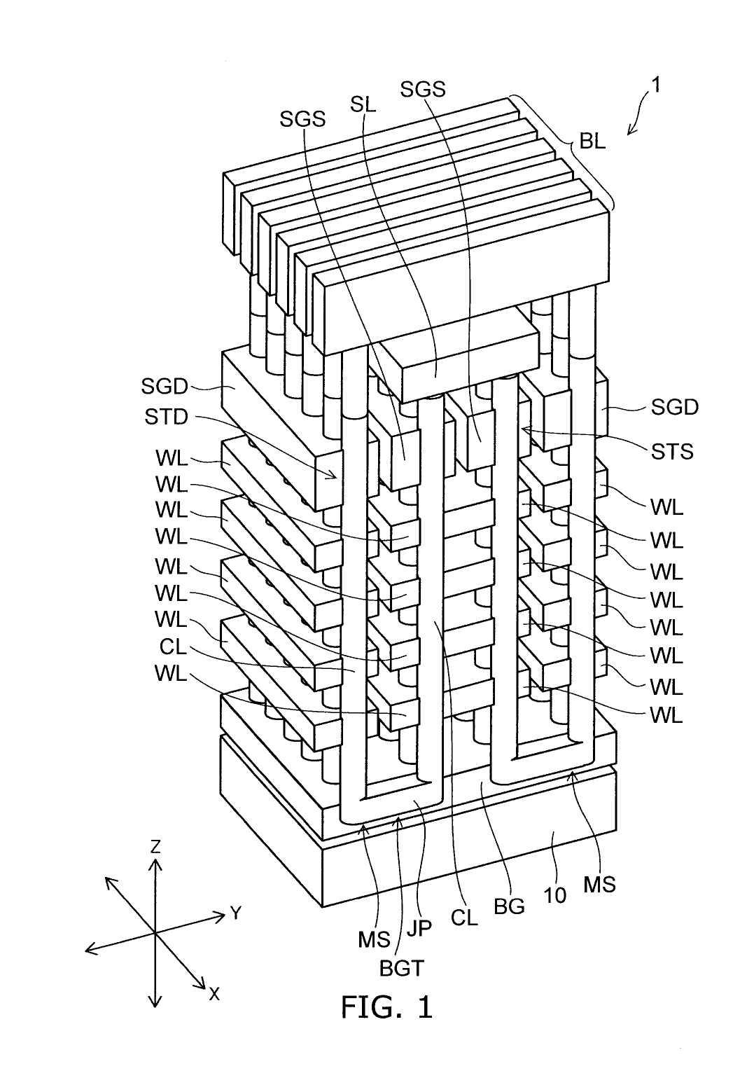

FIG. 1 is a schematic perspective view of a memory cell array 1 of a semiconductor memory device of the embodiment. In FIG. 1, in order to make the drawing easy to see, there is omitted illustration of an insulating layer between electrode layers WL, an insulating separation film that isolates a stacked body into a plurality of blocks.

In FIG. 1, two directions that are parallel to a major surface of a substrate 10 and are perpendicular to each other are set to be an X-direction and a Y-direction, and a direction perpendicular to both these X-direction and Y-direction is set to be a Z-direction (stacking direction).

The memory cell array 1 has a plurality of memory strings MS.

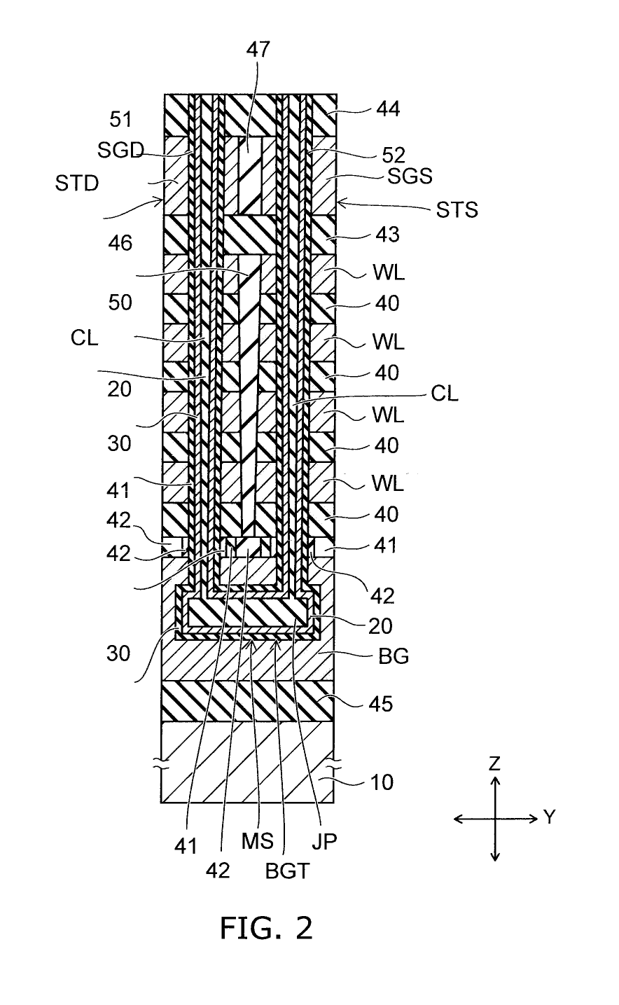

FIG. 2 is a schematic cross-sectional view of the memory string MS. FIG. 2 shows a cross-section parallel to a Y-Z face in FIG. 1.

The memory cell array 1 has a stacked body in which a plurality of the electrode layers WL and a plurality of insulating layers 40 have been alternately stacked one by one. The stacked body is provided on a back gate BG as a lower gate layer. The number of the electrode layers WL shown in FIG. 2 is one example, and that the number of the electrode layers WL is arbitrary.

The back gate BG is provided on the substrate 10 through an insulating layer 45. The back gate BG and the electrode layer WL are layers each containing silicon as a main component. Furthermore, the back gate BG and the electrode layer WL contain boron as an impurity for imparting conductivity to a silicon layer. In addition, the electrode layer WL may contain a metal silicide.

One memory string MS is formed into a U shape that has a pair of columnar parts CL extending in the Z-direction, and a coupling part JP for coupling lower ends of the pair of columnar parts CL. The columnar part CL is formed into, for example, a cylindrical shape, penetrates through the stacked body, and reaches the back gate BG.

A drain-side selection gate SGD is provided at one upper end of the pair of columnar parts CL in the U-shaped memory string MS, and a source-side selection gate SGS is provided at the other upper end thereof. The drain-side selection gate SGD and the source-side selection gate SGS are provided on the electrode layer WL of an uppermost layer via an insulating layer 43.

The drain-side selection gate SGD and the source-side selection gate SGS are layers containing silicon as a main component. Furthermore, the drain-side selection gate SGD and the source-side selection gate SGS contain boron as an impurity for imparting conductivity to the silicon layer.

The drain-side selection gate SGD and the source-side selection gate SGS as upper selection gates are thicker than the electrode layer WL of one layer. In addition, the back gate BG as a lower selection gate is thicker than the electrode layer WL of one layer.

The drain-side selection gate SGD and the source-side selection gate SGS are separated in the Y-direction by an insulating separation film 47. The stacked body under the drain-side selection gate SGD and the stacked body under the source-side selection gate SGS are separated in the Y-direction by an insulating separation film 46. Namely, the stacked body between the pair of columnar parts CL of the memory string MS is separated in the Y-direction by the insulating separation films 46 and 47.

A source line (for example, a metal film) SL shown in FIG. 1 is provided on the source-side selection gate SGS via the insulating layer. A plurality of bit lines (for example, metal films) BL shown in FIG. 1 is provided on the drain-side selection gate SGD and the source line SL via the insulating layer. Each bit line BL extends in the Y-direction.

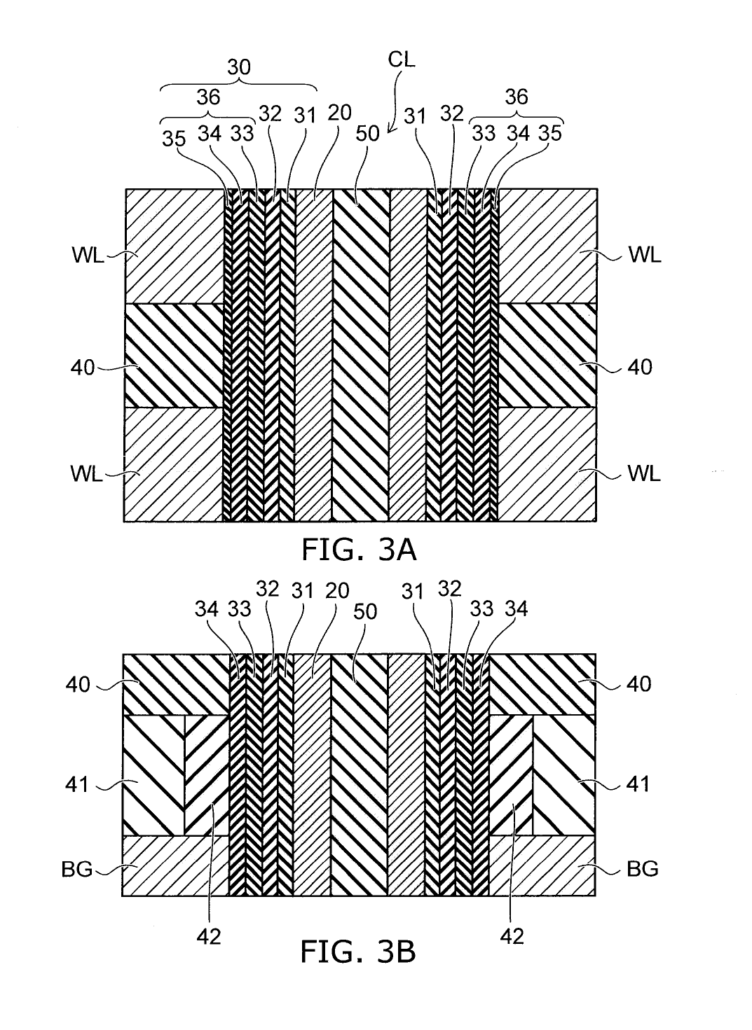

FIG. 3A is an enlarged schematic cross-sectional view of the columnar part CL of the memory string MS. FIG. 3A shows the columnar part CL in the stacked body including the plurality of electrode layers WL.

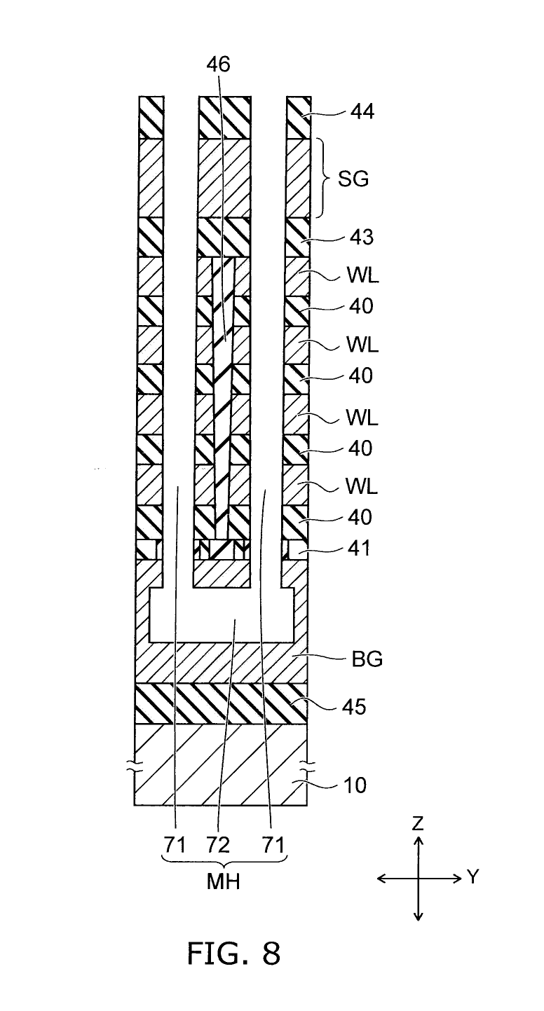

The columnar part CL is formed in a U-shaped memory hole MH shown in FIG. 8. The memory hole MH is formed in the stacked body including an upper selection gate SG, the plurality of electrode layers WL, and the back gate BG.

A channel body 20 as a semiconductor channel is provided in the memory hole MH. The channel body 20 is, for example, a silicon film.

A memory film 30 is provided between an inner wall of the memory hole MH and the channel body 20. The memory film 30 has a block film 36, a charge storage film 32, and a tunnel film 31. The block film 36, the charge storage film 32, and the tunnel film 31 are provided between the electrode layer WL and the channel body 20, in order from the electrode layer WL side.

The channel body 20 is provided in a cylindrical shape, and the cylindrical memory film 30 is provided so as to surround an outer peripheral face of the channel body 20. The electrode layer WL surrounds a periphery of the channel body 20 via the memory film 30. In addition, a core insulating film 50 is provided inside the channel body 20. The core insulating film 50 is, for example, a silicon oxide film.

The block film 36 is in contact with the electrode layer WL, the tunnel film 31 is in contact with the channel body 20, and the charge storage film 32 is provided between the block film 36 and the tunnel film 31.

The channel body 20 functions as a channel in a memory cell, and the electrode layer WL functions as a control gate of the memory cell. The charge storage film 32 functions as a data memory layer that stores charge injected from the channel body 20. Namely, the memory cell having a structure in which the control gate has surrounded a periphery of the channel is formed at an intersection part of the channel body 20 and each of the electrode layer WL.

A semiconductor memory device of the embodiment can electrically freely perform erasure/writing of data, and is a nonvolatile semiconductor memory device that can hold a memory content even when power is turned off.

The memory cell is, for example, a charge-trapping memory cell. The charge storage film 32 has a number of trap sites for capturing charges, and is, for example, a silicon nitride film.

When charges are injected into the charge storage film 32 from the channel body 20, or charges stored in the charge storage film 32 diffuse into the channel body 20, the tunnel film 31 serves as a potential barrier. The tunnel film 31 is an insulating film, and is, for example, a silicon oxide film.

The block film 36 prevents the charge stored in the charge storage film 32 from diffusing into the electrode layer WL. The block film 36 has a silicon oxide film (first silicon oxide film) 35, a silicon nitride film 34, and a silicon oxide film (second silicon oxide film) 33 which are provided in order from the electrode layer WL side.

The silicon oxide film 35 is in contact with the electrode layer WL. The silicon oxide film 35 is interposed between the electrode layer WL and the silicon nitride film 34, and the silicon nitride film 34 is not in contact with the electrode layer WL.

A film thickness of the silicon oxide film 35 is smaller than film thickness of each of the channel body 20, the tunnel film 31, the charge storage film 32, the silicon oxide film 33, and the silicon nitride film 34.

One of the silicon oxide film 33 and the silicon nitride film 34 may just be used in the block film 36. However, a stacked film of the silicon oxide film 33 and the silicon nitride film 34 is superior in charge blocking property to a single-layer film of one of them. Particularly, high blocking property is obtained by providing the silicon oxide film 33 on the charge storage film 32 side, and providing the silicon nitride film 34 on the electrode layer WL side.

Furthermore, according to the embodiment, the silicon oxide film 35 is provided between the silicon nitride film 34 and the electrode layer WL. The silicon oxide film 35 prevents diffusion of boron contained in the electrode layer WL, as will be described later.

As shown in FIGS. 1 and 2, a drain-side selection transistor STD is provided at one upper end of the pair of columnar parts CL in the U-shaped memory string MS, and a source-side selection transistor STS is provided at the other upper end thereof.

The memory cell, the drain-side selection transistor STD, and the source-side selection transistor STS are vertical transistors through which a current flows in the Z-direction.

The drain-side selection gate SGD functions as a gate electrode (control gate) of the drain-side selection transistor STD. Between the drain-side selection gate SGD and the channel bodies 20, there is provided an insulating film 51 (FIG. 2) functioning as a gate insulating film of the drain-side selection transistor STD. The channel body of the drain-side selection transistor STD is connected to the bit line BL at an upper part of the drain-side selection gate SGD.

The source-side selection gate SGS functions as a gate electrode (control gate) of the source-side selection transistor STS. Between the source-side selection gate SGS and the channel body 20, there is provided an insulating film 52 (FIG. 2) that functions as a gate insulating film of the source-side selection transistor STS. The channel body of the source-side selection transistor STS is connected to the source line SL at an upper part of the source-side selection gate SGS.

A back gate transistor BGT is provided at the coupling part JP of the memory string MS. The back gate BG functions as a gate electrode (control gate) of the back gate transistor BGT. The memory film 30 provided in the back gate BG functions as a gate insulating film of the back gate transistor BGT.

Between the drain-side selection transistor STD and the back gate transistor BGT, there is provided a plurality of memory cells in which the electrode layer WL of each layer serves as the control gate. In the same way, also between the back gate transistor BGT and the source-side selection transistor STS, there is provided a plurality of memory cells in which the electrode layer WL of each layer serves as the control gate.

The plurality of memory cells, the drain-side selection transistor STD, the back gate transistor BGT, and the source-side selection transistor STS are connected in series through the channel body 20, and constitute one U-shaped memory string MS. The memory string MS is arranged in plural numbers in the X-direction and the Y-direction, and thus the plurality of memory cells is three-dimensionally provided in the X-direction, the Y-direction, and the Z-direction.

Charge blocking property of the silicon nitride film is higher than that of the silicon oxide film. In addition, a stacked structure of the silicon nitride film and the silicon oxide film has blocking property higher than a single layer of the silicon nitride film. Particularly, when the silicon oxide film is provided on the charge storage film 32 side, and the silicon nitride film is provided on the electrode layer WL side, high blocking property can be obtained.

When the silicon nitride film is in contact with the electrode layer WL in such a block film structure, there has been a problem in which boron in the electrode layer WL tends to move to the silicon nitride film by heat treatment in a process after formation of the block film. Movement of boron from the electrode layer WL to the silicon nitride film increases resistance of the electrode layer WL. Furthermore, there is concern that depletion is generated when a voltage is applied to the electrode layer WL, and that reliability is reduced.

Consequently, according to the embodiment, the silicon oxide film 35 is provided between the silicon nitride film 34 in the block film 36 and the electrode layer WL. The silicon oxide film 35 suppresses boron lost from the electrode layer WL. Therefore, the increase in the resistance of the electrode layer WL in the subsequent heat treatment process can be suppressed, and thus reliability can be improved by suppression of depletion.

Boron is absorbed in some degree also by the silicon oxide film 35 from the electrode layer WL by the heat treatment. However, a small amount of boron is absorbed by the silicon oxide film compared with the silicon nitride film. Since the silicon oxide film 35 is very thin and is, for example, not more than 1 nm, the number of boron (boron concentration) per unit volume in the silicon oxide film 35 becomes larger than the number of boron (boron concentration) per unit volume in the electrode layer WL.

In addition, the insulating layer 40 stacked on and under the electrode layer WL is a silicon oxide layer. Therefore, an upper face and a lower face of the electrode layer WL are also in contact with the silicon oxide film, and boron lost from the upper face side and the lower face side of the electrode layer WL is also suppressed.

In addition, the electrode layer WL is not in contact with the silicon nitride film 34, but is in contact with the silicon oxide film 35, and thus charge movement (leak current) between the electrode layers WL adjacent to each other in the Z-direction (stacking direction) can also be suppressed.

In addition, when a film with which the electrode layer WL is in contact is the silicon oxide film, a barrier height between the electrode layer WL and the silicon oxide film increases more than a case where the electrode layer WL is in contact with the silicon nitride film, there are suppressed a back-tunneling electron passing through the electrode layer WL to the memory film 30 side at the time of erasure operation, and a back-tunneling hole passing through the electrode layer WL to the memory film 30 side at the time of writing operation, and thus reliability can be improved.

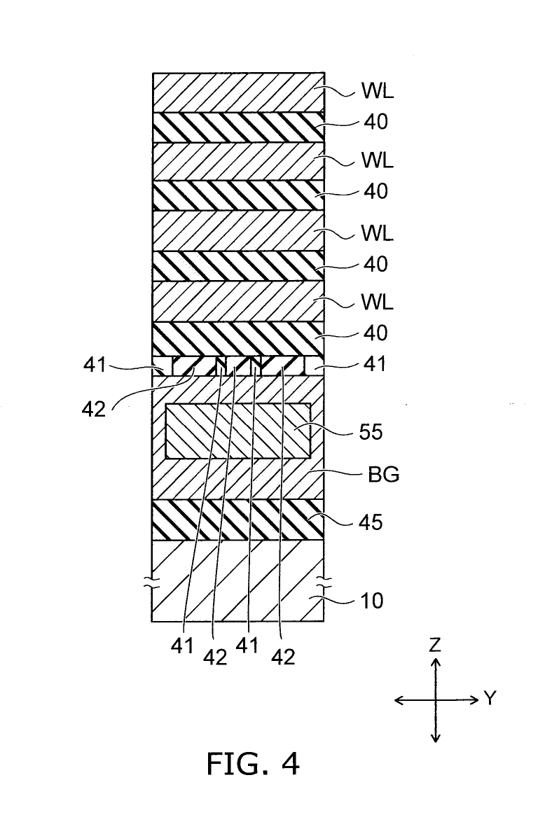

Next, a manufacturing method of the semiconductor memory device of the embodiment will be described with reference to FIGS. 4 to 9.

As shown in FIG. 4, the back gate BG is formed on the substrate 10 via the insulating layer 45. A concave part is formed in the back gate BG, and a sacrificial film 55 is buried in the concave part. The sacrificial film 55 is, for example, a silicon nitride film.

A metal oxide film 42 is formed on the back gate BG, and the metal oxide film 42 is patterned and is selectively removed. A silicon oxide film 41 is formed at a portion from which the metal oxide film 42 has been removed. The metal oxide film 42 is, for example, a tantalum oxide film (TaO film).

The plurality of insulating layers 40 and electrode layers WL are alternately stacked one by one on the metal oxide film 42 and the silicon oxide film 41. The electrode layer WL is a silicon layer containing boron as an impurity.

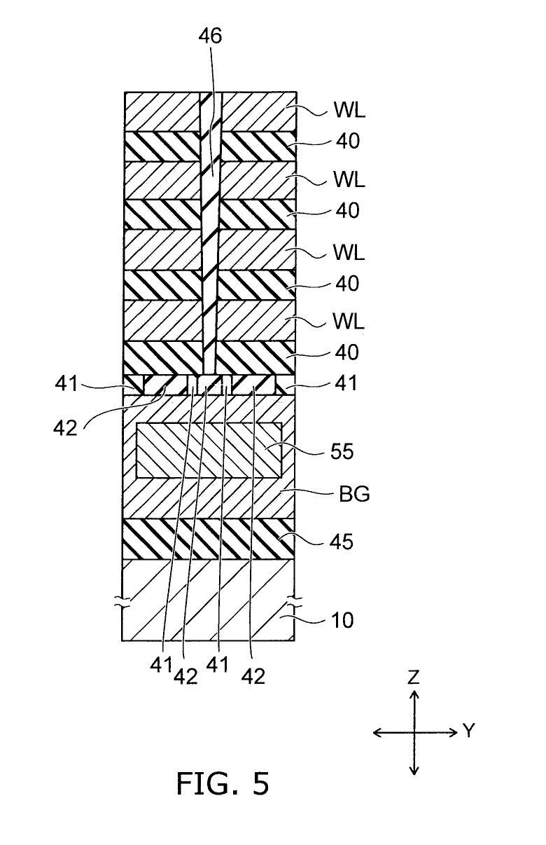

After the formation of a stacked body including the electrode layers WL and the insulating layers 40, a slit is formed in the stacked body. A lower end of the slit reaches the metal oxide film 42. The insulating layer 40 is a silicon oxide layer, and the electrode layer WL is a boron-doped silicon layer. The slit is formed by an RIE (reactive ion etching) method. At this time, the metal oxide film 42 that is formed of a material different from the insulating layer 40 and the electrode layer WL and that has a high etching selectivity functions as an etching stopper. The insulating separation film 46 is, as shown in FIG. 5, buried in the slit. The insulating separation film 46 is, for example, a silicon nitride film.

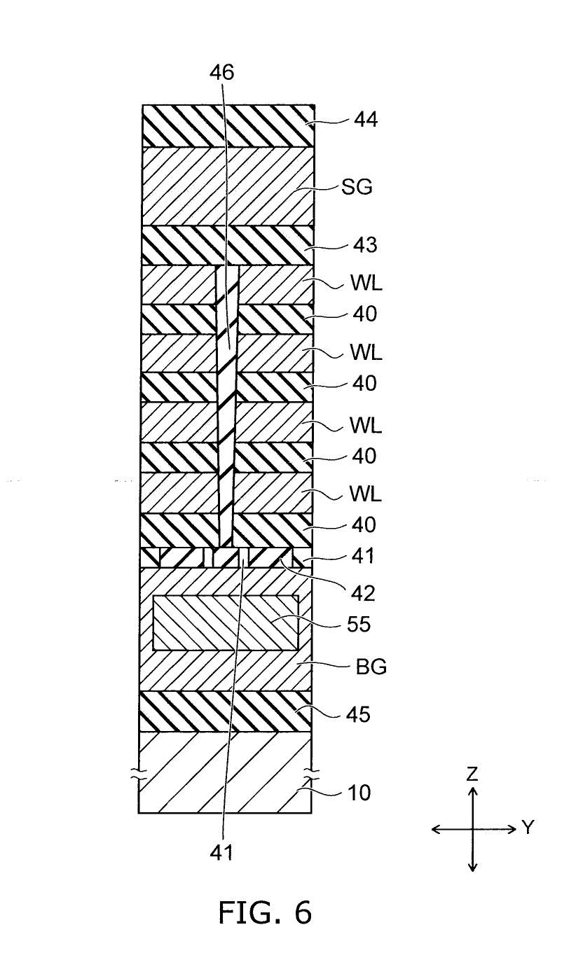

After the formation of the insulating separation film 46, the insulating layer 43 is, as shown in FIG. 6, formed on the electrode layer WL of the uppermost layer, the upper selection gate SG serving as the drain-side selection gate SGD or the source-side selection gate SGS is further formed on the insulating layer 43, and an insulating layer 44 is further formed on the upper selection gate SG.

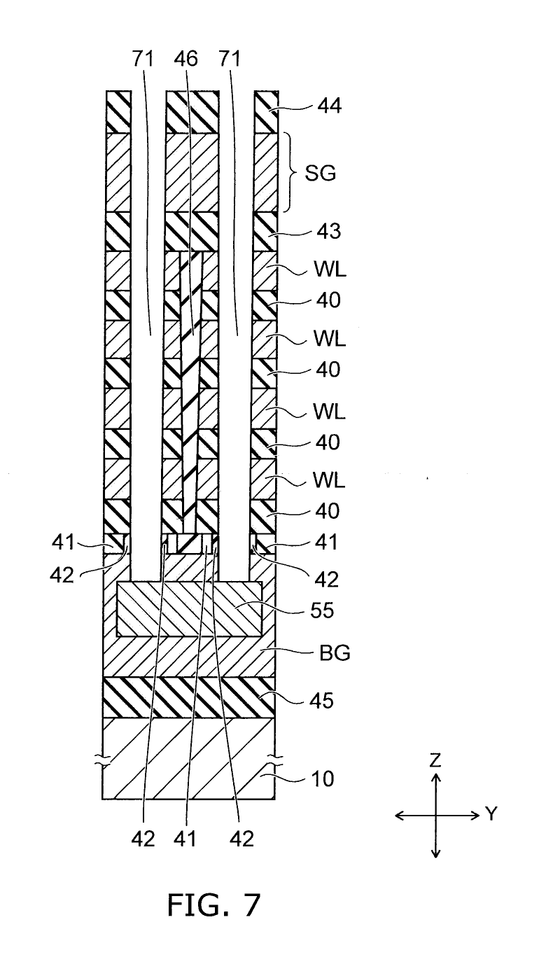

Next, as shown in FIG. 7, a plurality of holes 71 is formed in the above-described stacked body. The hole 71 is, for example, formed by the RIE method using a mask, which is not shown.

A lower end of the hole 71 reaches the sacrificial film 55, and the sacrificial film 55 is exposed to a bottom of the hole 71. A pair of holes 71 is formed on one sacrificial film 55. The hole 71 penetrates through a portion at which the metal oxide film 42 has been formed, and reaches the sacrificial film 55.

The insulating layers 40, 43, and 44 are silicon oxide layers, and the electrode layer WL and the upper selection gate SG are boron-doped silicon layers. The insulating layers 40, 43, and 44, the electrode layer WL, and the upper selection gate SG are continuously etched by, for example, a same etching condition. At this time, the metal oxide film 42 formed of the material different from the silicon oxide layer and the silicon layer functions as the etching stopper.

Progressing degree of etching of the plurality of holes 71 is made uniform at a position of the metal oxide film 42, and shapes and depths of the plurality of holes 71 can be controlled to be uniform.

After the formation of the holes 71, the sacrificial film 55 is removed by etching through the holes 71. The sacrificial film 55 is removed by, for example, wet etching.

A concave part 72 formed in the back gate BG, as shown in FIG. 8, appears by the removal of the sacrificial film 55. The pair of holes 71 is connected to one concave part 72. Namely, the lower ends of each of the pair of holes 71 are connected to the one common concave part 72, and one U-shaped memory hole MH is formed.

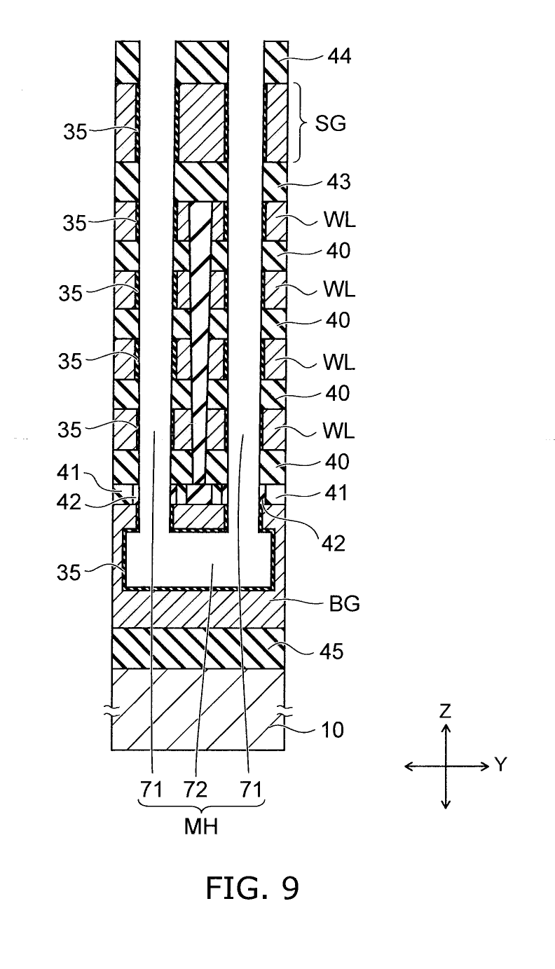

After the formation of the memory hole MH, there is performed cleaning treatment of organic substances or the like deposited on a hole inner wall at the time of RIE. For example, there is performed wet treatment using a chemical liquid such as ozone water, or a mixture of sulfuric acid and hydrogen peroxide. In the wet treatment, the thin silicon oxide film 35 having a thickness not more than 1 nm is, as shown in FIG. 9, formed on surfaces of the silicon layers (the electrode layer WL, the upper selection gate SG, the back gate BG) exposed to the inner wall of the memory hole MH. Accordingly, the silicon oxide film 35 for suppressing the above-mentioned diffusion of boron can be formed without adding a process.

A silicon oxide film is not formed on a surface of the metal oxide film (for example, the TaO film) 42 by the above-described chemical liquid treatment.

After that, each film shown in FIGS. 3A and 3B is formed in order on the inner wall of the memory hole MH. Namely, as shown in FIG. 3A, there is obtained a structure in which the silicon oxide film 35 is interposed between the electrode layer WL and the silicon nitride film 34.

FIG. 3B is an enlarged schematic cross-sectional view of a portion in which the columnar part CL of the memory string MS penetrates through a layer between a lowermost layer (for example, the insulating layer 40) of the stacked body and the back gate BG.

As mentioned above, the silicon oxide film is not formed on the metal oxide film 42 by the chemical liquid treatment after the hole formation. Accordingly, the silicon nitride film 34 is formed in contact with a side surface of the metal oxide film 42.

Namely, the metal oxide film 42 is provided on a side surface of the silicon nitride film 34 between the back gate BG and the stacked body including the electrode layer WL, and the silicon oxide film (third silicon oxide film) 41 is further provided on the side surface of the metal oxide film 42. A film thickness of the silicon oxide film 41 is larger than a film thickness of the silicon oxide film 35 formed on a side surface of the electrode layer WL. In addition, the film thickness of the silicon oxide film 41 is larger than a film thickness of the block film 36.

A metal oxide film such as a TaO film has lower charge blocking property than a silicon oxide film or a silicon nitride film. However, according to the embodiment, the silicon oxide film 41 thicker than the block film 36 is provided on the side surface of the metal oxide film 42. Therefore, movement of charges between the back gate BG and the charge storage film 32 located at an upper part of the back gate BG can be suppressed by the silicon oxide film 41. In addition, the metal oxide film 42 such as the TaO film is formed closer to an inside of the silicon oxide film 41 around the columnar part CL, and thus a fringe electric field of the portion becomes strong, channel resistance can be lowered, and an on-state current Ion is improved.

After the formation of the memory film 30, the channel body 20, and the core insulating film 50 in the memory hole MH, the upper selection gate SG between the pair of columnar parts CL is, as shown in FIG. 2, separated in the Y-direction by the insulating separation film 47.

After that, the source line SL, the bit line BL, and the like shown in FIG. 1 are formed on the insulating layer 44.

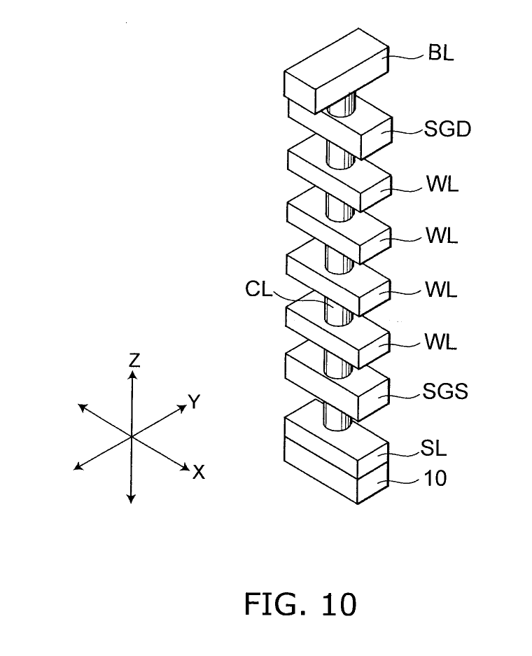

A configuration of a memory string is not limited to a U shape, but may be an I shape as shown in FIG. 10. Only a conductivity portion is shown in FIG. 10, and illustration of an insulating portion is omitted. In the structure, the source line SL is provided on the substrate 10, the source-side selection gate (or the lower selection gate) SGS is provided on the substrate 10, the plurality of electrode layers WL are provided on the source-side selection gate SGS, and the drain-side selection gate (or the upper selection gate) SGD is provided between the electrode layer WL of the uppermost layer and the bit line BL.

Also in such an I-shaped memory string, the silicon oxide film 35 is provided between the silicon nitride film 34 in the block film 36 of the columnar part CL and the electrode layer WL. The silicon oxide film 35 suppresses boron lost from the electrode layer WL. Therefore, the increase in the resistance of the electrode layer WL in the subsequent heat treatment process can be suppressed, and reliability can be improved by suppression of depletion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body having a plurality of electrode layers containing boron and silicon, and a plurality of insulating layers each provided between the electrode layers;
a channel body penetrating through the stacked body and extending in a stacking direction of the stacked body; and
a memory film provided between the channel body and each of the electrode layer,
the memory film including a tunnel film, a charge storage film, and a block film, provided in order from the channel body side, and
the block film including a silicon nitride film, and a first silicon oxide film provided between the silicon nitride film and the electrode layer and being in contact with the electrode layer.

2. The device according to claim 1, wherein a thickness of the first silicon oxide film is thinner than a thickness of the silicon nitride film.

3. The device according to claim 1, wherein the block film further has a second silicon oxide film provided between the silicon nitride film and the charge storage film.

4. The device according to claim 3, wherein a thickness of the first silicon oxide film is thinner than a thickness of the second silicon oxide film.

5. The device according to claim 1, wherein
a lower gate layer is provided below the stacked body,
a metal oxide film is provided on a side surface of the silicon nitride film between the lower gate layer and the stacked body, and
a third silicon oxide film having a thickness thicker than a thickness of the first silicon oxide film is provided on a side surface of the metal oxide film.

6. The device according to claim 5, wherein the thickness of the third silicon oxide film is thicker than a thickness of the block film.

7. The device according to claim 5, wherein the metal oxide film contains TaO.

8. The device according to claim 1, wherein a thickness of the first silicon oxide film is thinner than a thickness of the channel body.

9. The device according to claim 1, wherein a thickness of the first silicon oxide film is thinner than a thickness of the tunnel film.

10. The device according to claim 1, wherein a thickness of the first silicon oxide film is thinner than a thickness of the charge storage film.

11. The device according to claim 1, wherein the silicon nitride film is not in contact with the electrode layer.

12. The device according to claim 1, wherein a thickness of the first silicon oxide film is not more than 1 nm.

13. The device according to claim 1, wherein the insulating layer contains a silicon oxide.

14. A manufacturing method of a semiconductor memory device comprising:
forming a stacked body on a substrate, the stacked body having a plurality of electrode layers containing boron and silicon, and a plurality of insulating layers each provided between the electrode layers;
forming a hole penetrating through the stacked body;
forming a block film, a charge storage film, and a tunnel film on a side wall of the hole in that order; and
forming a channel body on a side wall of the tunnel film,
the forming the block film including:
forming a first silicon oxide film on the side wall of the hole so as to be in contact with the electrode layer exposed to the hole; and
forming a silicon nitride film on a side wall of the first silicon oxide film.

15. The method according to claim 14, wherein after the hole is formed, the first silicon oxide film is formed on the side wall of the hole by wet treatment.

16. The method according to claim 15, wherein ozone water, or a mixture of sulfuric acid and hydrogen peroxide is used for the wet treatment.

17. The method according to claim 14, wherein the forming the block film further has forming a second silicon oxide film on a side wall of the silicon nitride film.

18. The method according to claim 14, further comprising:
forming a metal oxide film on the substrate before forming the stacked body on the substrate;
selectively removing the metal oxide film; and
forming a third silicon oxide film at a portion from which the metal oxide film has been removed, wherein
the hole penetrates through the stacked body and reaches the metal oxide film.

19. The method according to claim 18, further comprising:
forming a slit penetrating through the stacked body and reaching the metal oxide film; and
forming an insulating film in the slit.

20. The method according to claim 18, wherein the forming the block film includes forming the silicon nitride film on a side surface of the metal oxide film.
